(19) United States
(12) Patent Application Publication
(10) Pub. No.: US 2026/0372176 A1
(43) Pub. Date: Nov. 19, 2026

(54) MANUFACTURING METHOD FOR WINDOW AND ELECTRONIC DEVICE INCLUDING THE WINDOW

(71) Applicant: Samsung Display Co., Ltd., Yongin-si (KR)

(72) Inventor: HYUNHO JEONG, Yongin-si (KR)

(21) Appl. No.: 19/652,882

(22) Filed: Apr. 20, 2026

(30) Foreign Application Priority Data
May 13, 2025 (KR) 10-2025-0061809

(51) Int. Cl. H10W 74/10; H10W 74/01

(52) U.S. Cl. CPC H10W 74/127; H10W 74/016

(57) ABSTRACT

A manufacturing method for a window including providing a base substrate including a first region and a second region adjacent to the first region, forming a guide dam by applying a peelable ink onto a portion of the first region adjacent to the second region, forming a bezel pattern by applying a bezel ink onto the second region, and removing the guide dam.

### CROSS-REFERENCE TO RELATED APPLICATION

The present application claims priority to and the benefit of Korean Patent Application No. 10-2025-0061809, filed on May 13, 2025, in the Korean Intellectual Property Office, the entire disclosure of which is incorporated herein by reference.

### BACKGROUND

Embodiments of the present disclosure herein relate to a manufacturing method for a window, and for example, to a manufacturing method for a window included in a display device.

A window member for screen protection is installed on the front surface of a display panel to protect the display panel. For example, the window member is attached and fixed on the outer surface of the display panel so that a user input or a device output may be recognized by the user from the outside.

### SUMMARY

Embodiments of the present disclosure provide a window manufacturing method capable of enhancing the reliability of a bezel pattern for light blocking when forming the bezel pattern in a bezel portion of the window.

Aspects according to one or more embodiments of the present disclosure include a manufacturing method for a window including providing a base substrate including a first region and a second region adjacent to the first region, forming a guide dam by applying a peelable ink onto a portion of the first region adjacent to the second region, forming a bezel pattern by applying a bezel ink onto the second region, and removing the guide dam.

In one or more embodiments, a height of the guide dam may be greater than a height of the bezel pattern.

In one or more embodiments, a height of the guide dam may be 0.1 mm to 1.0 mm.

In one or more embodiments, a height of the bezel pattern may be 0.01 mm to 0.02 mm.

In one or more embodiments, the forming of the guide dam may include jetting the peelable ink onto the base substrate through an inkjet process.

In one or more embodiments, the forming of the bezel pattern may include applying the bezel ink onto the base substrate through a screen-printing process.

In one or more embodiments, the peelable ink may include a resin having a hydrogen bond.

In one or more embodiments, the removing of the guide dam may include dipping the base substrate in an aqueous solution.

In one or more embodiments, the peelable ink may include a resin including a carbonyl group.

In one or more embodiments, the removing of the guide dam may include dipping the base substrate in an aqueous solution including sodium hydroxide.

In one or more embodiments, the manufacturing method of a window may further include, after the forming of the guide dam, re-applying the peelable ink onto the guide dam.

In one or more embodiments, the manufacturing method for a window may further include, after the forming of the guide dam, curing the guide dam by irradiating the guide dam with ultraviolet rays.

In one or more embodiments, the manufacturing method for a window may further include, after the curing of the guide dam, re-applying the peelable ink onto the guide dam.

In one or more embodiments, the guide dam and the bezel pattern may be in direct contact with each other.

In one or more embodiments, on a plane, an inner edge of the bezel pattern may overlap a boundary between the first region and the second region.

In one or more embodiments, the bezel pattern may have an asymmetrical shape on a cross-section.

In one or more embodiments, the bezel pattern may have a light blocking property.

In one or more embodiments, the bezel ink may include either polyurethane or polyacrylate.

In one or more embodiments of the present disclosure , an electronic device includes a window manufactured by a window manufacturing method including providing a base substrate including a first region and a second region adjacent to the first region, forming a guide dam by applying a peelable ink onto a portion of the first region adjacent to the second region, forming a bezel pattern by applying a bezel ink onto the second region, and removing the guide dam; and a display panel under the window.

In one or more embodiments, the bezel pattern may be formed on a surface where the window faces the display panel.

### BRIEF DESCRIPTION OF THE DRAWINGS

The accompanying drawings are included to provide a further understanding of the present disclosure, and are incorporated in and constitute a part of this disclosure. The drawings illustrate embodiments of the present disclosure and, together with the description, serve to explain principles of the present disclosure. In the drawings:

FIG. 1 is a block diagram of an electronic device according to the present disclosure;

FIG. 2 illustrates schematic views of electronic devices according to various suitable embodiments;

FIG. 3 is a perspective view of an electronic device according to one or more embodiments of the present disclosure;

FIG. 4A is an exploded perspective view of an electronic device according to one or more embodiments of the present disclosure;

FIG. 4B is an exploded perspective view of a window according to one or more embodiments of the present disclosure;

FIG. 5 is a flowchart of a manufacturing method for a window according to one or more embodiments of the present disclosure;

FIGS. 6-15 are views illustrating respective acts of a manufacturing method for a window according to one or more embodiments of the present disclosure; and

FIGS. 16 and 17 are views illustrating respective acts of a manufacturing method for a window according to one or more embodiments of the present disclosure.

### DETAILED DESCRIPTION

In the present disclosure, various suitable modifications may be made and various suitable forms may be applied, and specific embodiments will be illustrated in the drawings and described in more detail in the text. However, this is not intended to limit the present disclosure to a specific disclosure form, it should be understood to include all changes, equivalents, and substitutes included in the spirit and scope of the present disclosure.

In this disclosure, it will be understood that when an element (or a region, a layer, a portion, and/or the like) is referred to as being "on", "connected to" or "coupled to" another element, it may be directly arranged on, connected to, or coupled to the other element, or other elements may be arranged therebetween.

Like reference numerals or symbols refer to like elements throughout. In the drawings, the thickness, ratio, and size of the elements may be exaggerated for effectively describing the technical contents. As used herein, the term "and/or" includes any and all combinations of one or more of the associated listed elements.

It will be understood that, although the terms “first”, “second”, and/or the like may be used herein to describe one or more suitable elements, the elements are not to be limited by these terms. These terms are only used to distinguish one element from another element. For instance, a first element could be termed a second element without departing from the scope of the present disclosure. Similarly, a second element could be termed a first element. In this disclosure, the singular expressions "a", "an" and "the" are intended to include the plural forms as well, unless the context clearly indicates otherwise.

In one or more embodiments, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this disclosure, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure are described with reference to the accompanying drawings.

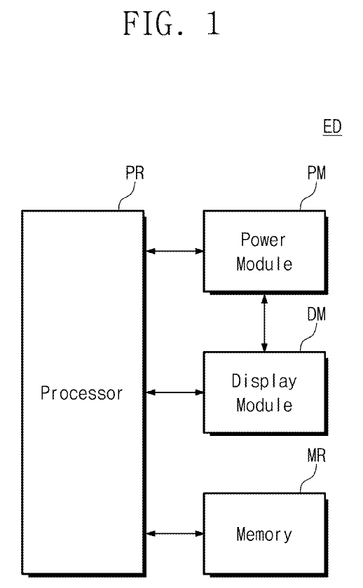

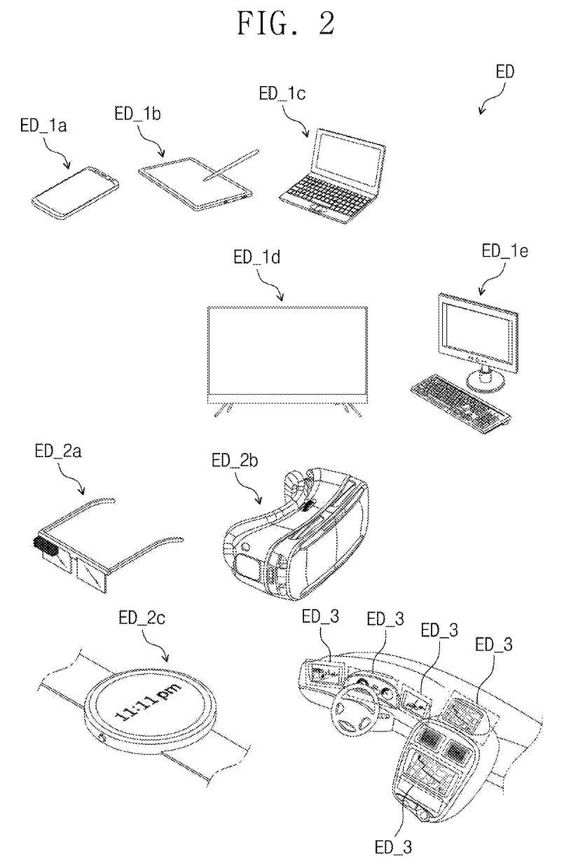

FIG. 1 is a block diagram of an electronic device according to the present disclosure. FIG. 2 illustrates schematic views of electronic devices according to various suitable embodiments.

FIG. 1 is a block diagram of an electronic device according to the present disclosure.

An electronic device according to the present disclosure may be provided in various suitable shapes. The electronic device according to the present disclosure may further include a module or device having another additional function.

Referring to FIG. 1, an electronic device ED according to one or more embodiments may include a display module DM, a processor PR, a memory MR, and a power module PM.

The processor PR may include at least one among a central processing unit (CPU), an application processor (AP), a graphic processing unit (GPU), a communication processor (CP), an image signal processor (ISP), or a controller.

The memory MR may store data and/or information required for an operation of the processor PR or the display module DM. When the processor PR executes an application stored in the memory MR, an image data signal and/or an input control signal may be transferred to the display module DM, and the display module DM may process the received signal and output image information through a display screen.

The power module PM may include a power supply module, such as a power adaptor or a battery device, and a power conversion module that converts power supplied by the power supply module to generate power required for an operation of the electronic device ED.

Among individual modules that are functionally included in a single module, some may be included in the display device DM, and others may be provided separately from the display device DM within the electronic device ED.

FIG. 2 illustrates schematic views of electronic devices according to various suitable embodiments.

Referring to FIG. 2, electronic devices according to various suitable embodiments may include not only an image displaying electronic device, such as a smart phone ED_1a, a tablet PC ED_1b, a laptop ED_1c, a TV ED_1d, or a desk monitor ED_1e, but also a wearable electronic device including a display module, such as smart glasses ED_2a, a head-mounted display ED_2b, or a smart watch ED_2c, and a vehicular electronic device ED_3 including a display module, such as a car dashboard, a center fascia, a center information display (CID) arranged in a dashboard, or a room mirror display.

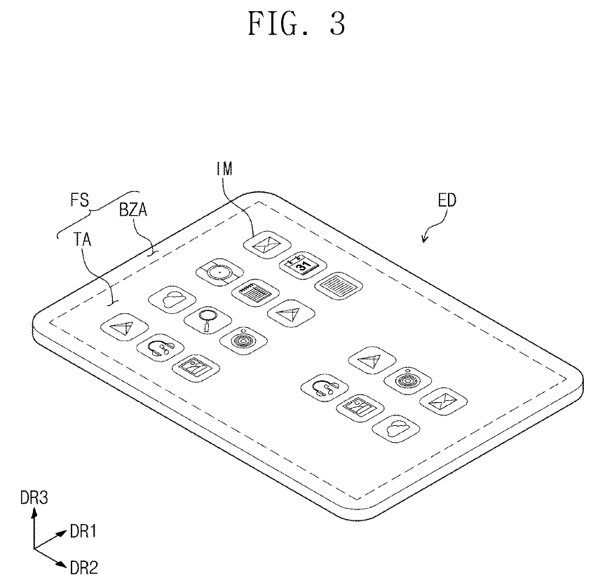

FIG. 3 is a perspective view of an electronic device according to one or more embodiments of the present disclosure.

In this embodiment, on a plane, the electronic device ED may have a rectangular shape having short sides extending in a first direction DR1 and long sides extending in a second direction DR2. However, one or more embodiments of the present disclosure are not limited thereto, and the electronic device ED may have various suitable shapes, such as a circular shape and a polygonal shape.

The electronic device ED may display an image IM in a third direction DR3 through a display surface FS parallel to a plane defined by the first direction DR1 and the second direction DR2. The third direction DR3 may be substantially parallel to a normal direction of the display surface FS. The display surface FS on which the image IM is displayed may correspond to a front surface of the electronic device ED. The image IM may include a still image as well as a moving image. In FIG. 3, icon images are illustrated as an example of the image IM.

In this embodiment, a front surface (or upper surface) and a rear surface (or lower surface) of each member or unit may be defined on the basis of the direction on which the image IM is displayed. The front surface and the rear surface may be opposed to each other in the third direction DR3, and a normal direction of each of the front surface and the rear surface may be parallel to the third direction DR3. A separate distance between the front surface and the rear surface, which are defined along the third direction DR, may correspond to a thickness of the member (or unit).

In this disclosure, “on a plane” may be defined as a state viewed from the third direction DR3. In this disclosure, “on a cross-section” may be defined as a state viewed from the first direction DR1 or the second direction DR2. The directions indicated by the first to third directions DR1, DR2, and DR3 are relative concepts and may thus be changed into other directions.

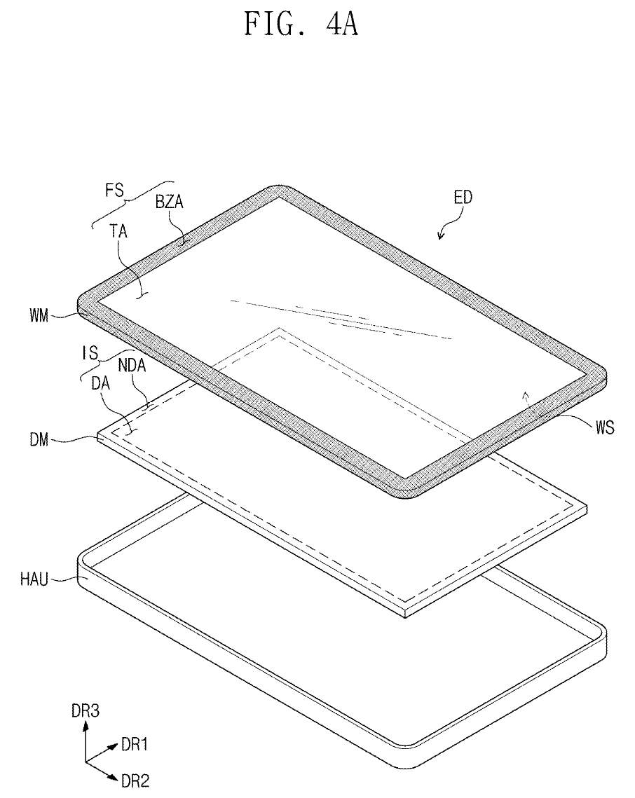

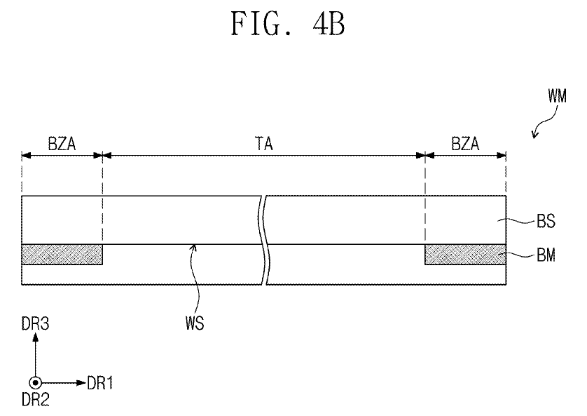

The display surface FS on which the image IM is displayed in the electronic device ED may correspond to the front surface of the electronic device ED, and correspond to a front surface of a window WM (see FIG. 4). Hereinafter, the display surface of the electronic device ED, the front surface of the electronic device ED, and the front surface of the window WM are denoted with the same reference numeral or symbol. In one or more embodiments, the electronic device ED may include, for example, a foldable display device including a folding region and a non-folding region, or a bendable display device including at least one bending portion.

FIG. 4A is an exploded perspective view of an electronic device according to one or more embodiments of the present disclosure. FIG. 4B is a cross-sectional view of a window according to one or more embodiments of the present disclosure.

Referring to FIG. 4A, the electronic device ED according to one or more embodiments may include a window WM, a display module DM, and a housing HAU.

The window WM may include an optically transparent insulating material. The window WM may include a transmission region TA and a bezel region BZA. A user may view an image provided through the transmission region TA corresponding to the front surface FS of the window WM.

The transmission region TA may be an optically transparent region. The bezel region BZA may be a region having a relatively low light transmittance compared to the transmission region TA. The bezel region BZA may have a color. The bezel region BZA may be adjacent to the transmission region TA and may surround the transmission region TA. The bezel region BZA may define the shape of the transmission region TA. However, embodiments are not limited to what is illustrated, and the bezel region BZA may be arranged adjacent to only one side of the transmission region TA or a portion of the bezel region BZA may not be provided.

In FIGS. 3 and 4A, the transmission region TA is illustrated as a quadrilateral shape. However, this is illustrated as an example, and the transmission region TA may have various suitable shapes and is not limited to any one embodiment.

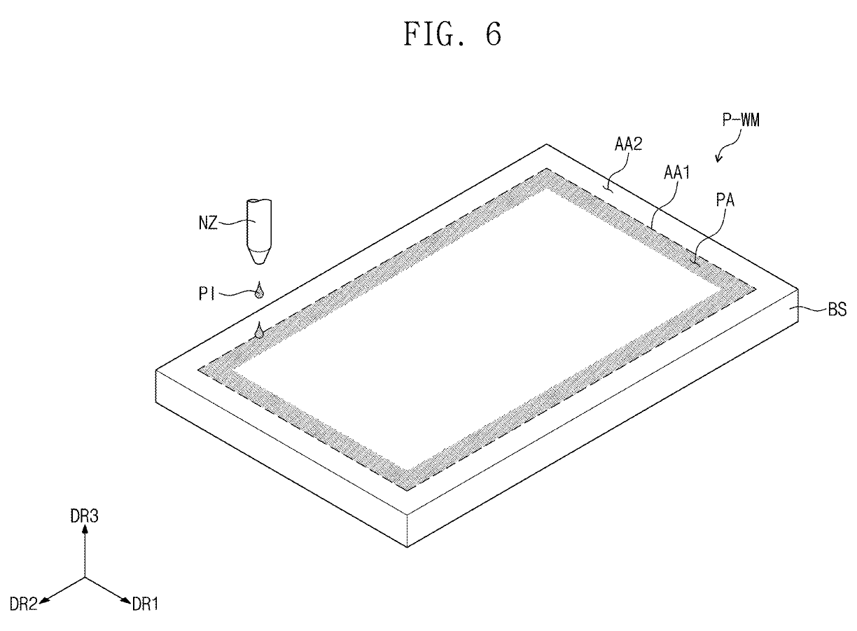

A first region AA1 (see FIG. 6) may overlap the transmission region TA, and a second region AA2 (see FIG. 6) may overlap the bezel region BZA.

A bezel ink BI may be applied onto a surface WS where the window WM faces the display panel DP.

Referring to FIG. 4B, the window WM may include a base substrate BS and a bezel pattern BM under the base substrate BS. The bezel pattern BM may have a light blocking property. The bezel pattern BM may block edge portions of the display module DM (see FIG. 4A) from being visible.

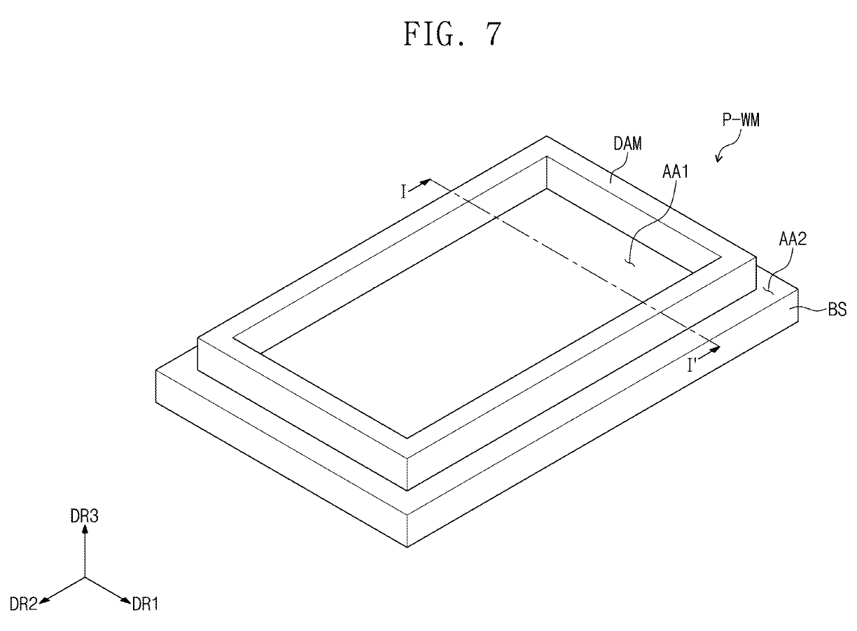

In a conventional window manufacturing process, a morphological defect such as a saw shape has occurred at the edge of the bezel pattern. This saw shape of the bezel pattern is caused by the dispersion of the bezel ink, and is a chronic defect that would occur in a screen-printing process. In contrast, according to the present disclosure, it is possible to prevent or reduce the dispersion of the bezel ink BI by using a guide dam DAM (see FIG. 7). Accordingly, the manufacturing method for a window according to the present disclosure may prevent or reduce the morphological defect of the bezel pattern BM.

The display module DM may be under the window WM. The display module DM may be a component that substantially generates the image IM. The image IM generated from the display module DM is displayed on a display surface IS and is viewed by the user through the transmission region TA from the outside.

The display module DM includes a display region DA and a non-display region NDA. The display region DA may be activated in response to an electrical signal. The non-display region NDA may be covered by the bezel region BZA. The non-display region NDA is adjacent to the display region DA. The non-display region NDA may surround the display region DA.

The housing HAU may accommodate the display module DM. The housing HAU may provide a base space in which the display module DM is to be arranged. The housing HAU may be arranged to cover the display module DM so that an upper surface, which is the display surface IS of the electronic device ED, is exposed. The housing HAU may cover a side surface and a bottom surface of the display module DM and may expose the entire upper surface. However, the embodiment is not limited thereto, and the housing HAU may cover a portion of the upper surface as well as the side surface and the bottom surface of the display module DM.

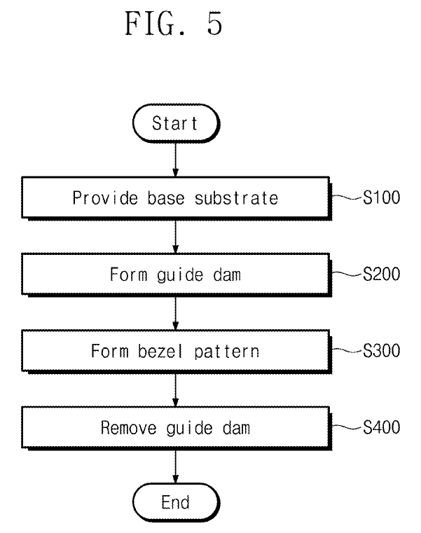

FIG. 5 is a flowchart of a manufacturing method for a window according to one or more embodiments of the present disclosure.

The manufacturing method for a window according to one or more embodiments of the present disclosure may include an act of providing a base substrate including a first region and a second region adjacent to the first region (S100), an act of forming a guide dam by applying a peelable ink onto a portion of the first region adjacent to the second region (S200), an act of forming a bezel pattern by applying a bezel ink onto the second region (S300), and an act of removing the guide dam (S400).

FIGS. 6-15 are views illustrating respective acts of a manufacturing method for a window according to one or more embodiments of the present disclosure.

FIGS. 6 and 7 are views illustrating that, after the act of providing the base substrate BS including the first region AA1 and the second region AA2 adjacent to the first region AA1 is performed, the act of forming the guide dam DAM by applying a peelable ink onto a portion of the first region AA1 adjacent to the second region is performed AA2 (S200) (see FIG. 5).

Referring to FIG. 6, a region onto which a peelable ink PI is applied may be referred to as a “dam-forming region PA”. The dam-forming region PA may be defined inside the first region AA1. The dam-forming region PA may be adjacent to a boundary between the first region AA1 and the second region AA2.

The act of forming the guide dam (S200) (see FIG. 5) may include an act of jetting the peelable ink PI onto the base substrate BS through an inkjet process.

FIG. 6 illustrates as an example that the peelable ink PI jetted by a nozzle NZ is applied onto the “dam-forming region PA”.

In this disclosure, the applied peelable ink PI may be referred to as a “guide dam DAM”. The guide dam DAM may have a specific width and height.

In this embodiment, the process of applying the peelable ink PI (see FIG. 6) is performed once, but the embodiment of the present disclosure is not limited to what is illustrated. The process of applying the peelable ink PI may be performed multiple times.

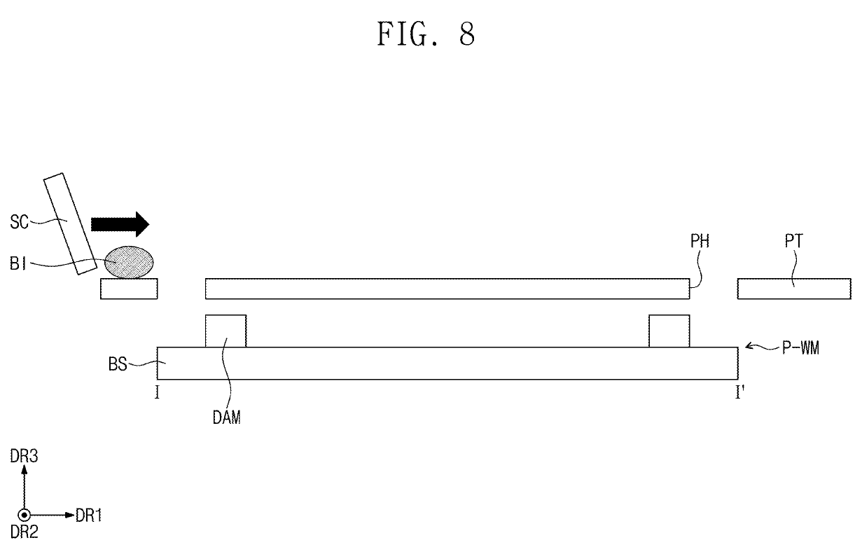

Referring to FIGS. 8-11, the act of forming the bezel pattern by applying the bezel ink onto the second region (S300) (see FIG. 5) may be performed.

FIGS. 8-11 may be cross-sectional views taken along line I-I' of FIG. 7.

The act of forming the bezel pattern (S300) may include an act of applying the bezel ink BI onto the base substrate BS through the screen-printing process.

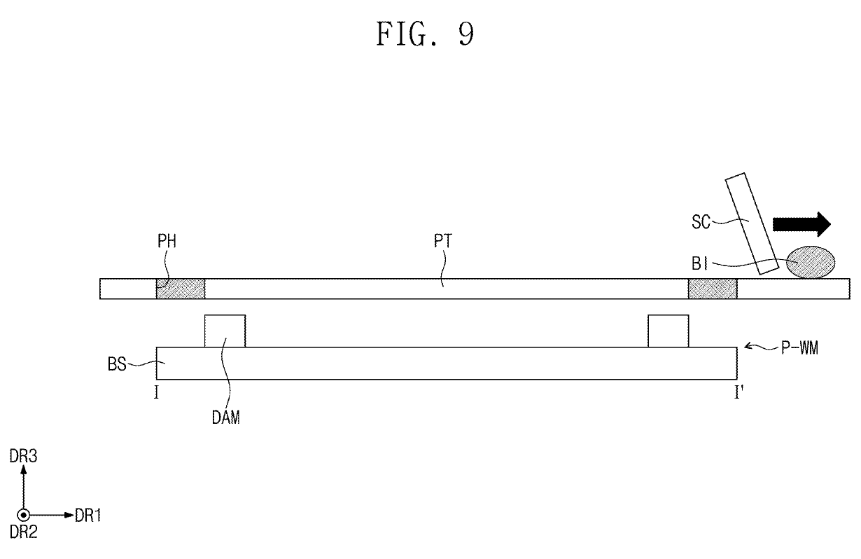

Referring to FIGS. 8 and 9, a plate PT for silk screen-printing may be arranged on the base substrate BS. The bezel ink BI may be arranged on one side of the upper surface of the plate PT. A scrapper SC may move in one direction and fill holes PH defined in the plate PT with the bezel ink BI.

FIG. 8 illustrates as an example that two holes PH which completely penetrate from the upper surface to the lower surface of the plate PT are defined in the plate PT. However, this is for convenience of explanation, and the plate PT may have fine holes PH defined between the fibers constituting the plate PT.

The scrapper SC may move in a first direction DR1 and cause the holes PH to be filled with the bezel ink BI.

The bezel ink BI may include either polyurethane or polyacrylate.

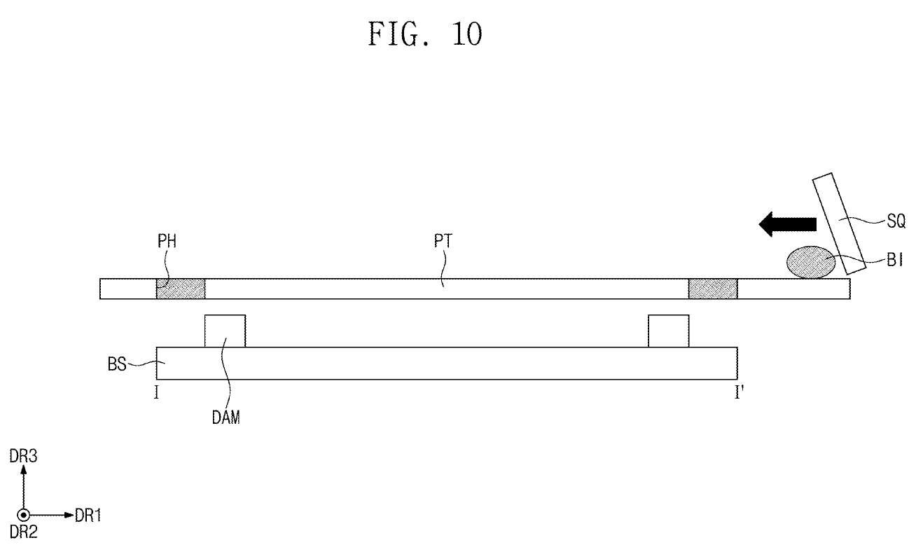

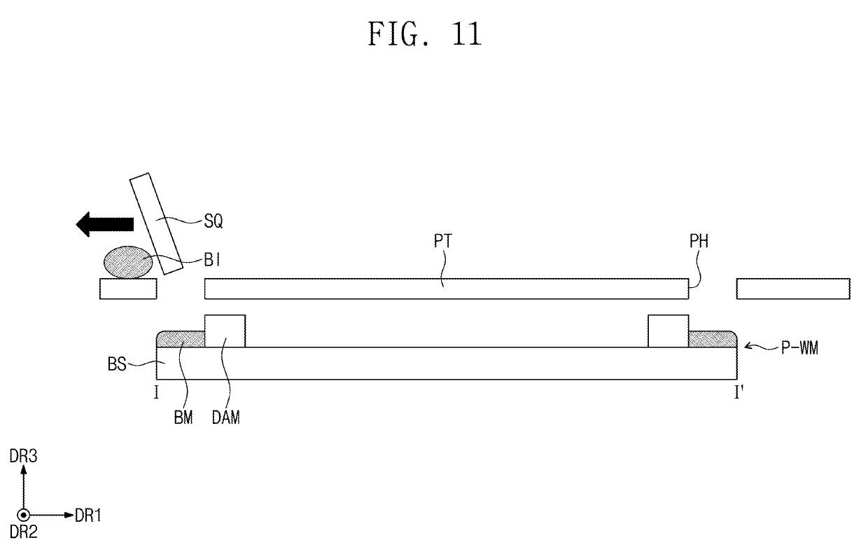

Referring to FIGS. 10 and 11, a squeeze SQ may move in the opposite direction of the one direction to cause the bezel ink BI filled in the holes PH to be jetted onto the base substrate BS.

FIGS. 10 and 11 illustrate as an example that the squeeze SQ moves in the opposite direction of the first direction DR1 to cause the bezel ink BI filled in the holes PH to be jetted onto the upper surface of the base substrate BS.

In this disclosure, the bezel ink BI applied onto the base substrate BS may be referred to as a “bezel pattern BM”.

Referring to FIG. 11, the applied peelable ink PI and the applied bezel ink BI may be in direct contact with each other. For example, the guide dam DAM may be in direct contact with the bezel pattern BM.

The shape of the bezel pattern BM may be defined by the shape of the guide dam DAM.

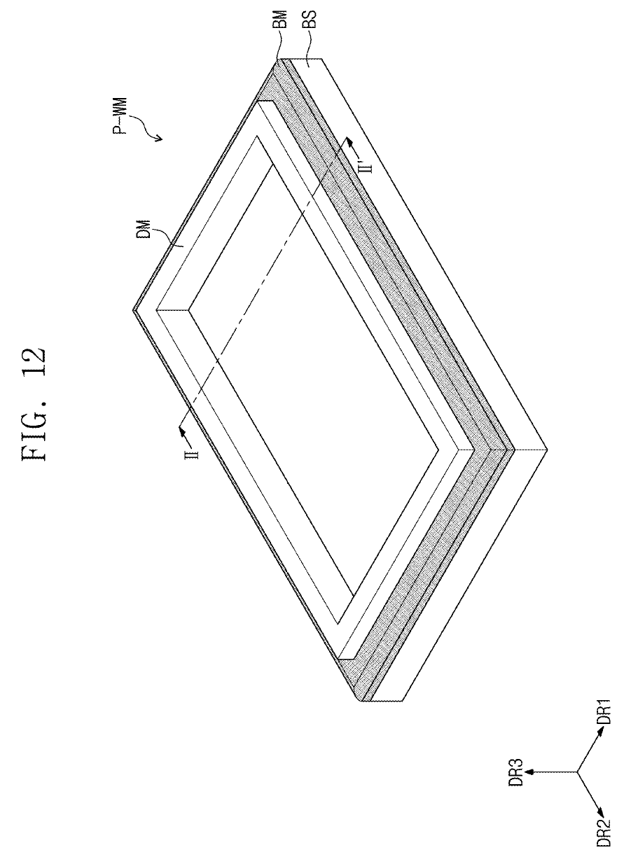

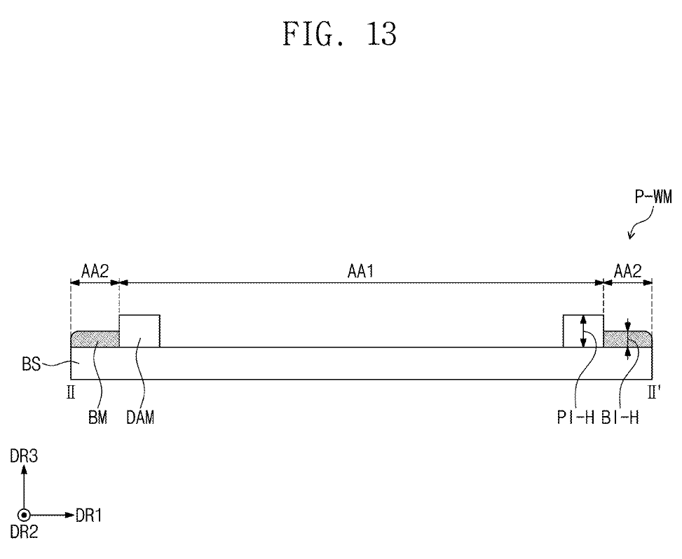

FIG. 12 is a perspective view illustrating the shapes of the guide dam DAM and the bezel pattern BM which have been formed. FIG. 13 is a cross-sectional view taken along line II-II' of FIG. 12.

Referring to FIGS. 12 and 13, the guide dam DAM may function to prevent or reduce the bezel ink BI from infiltrating into the first region AA1.

A height PI-H of the guide dam DAM may be greater than a height BI-H of the applied bezel pattern BM. In this embodiment, the height of PI-H of the applied peelable ink PI may be 0.1 mm to 1.0 mm. The height of BI-H of the applied bezel ink BI may be 0.01 mm to 0.02 mm.

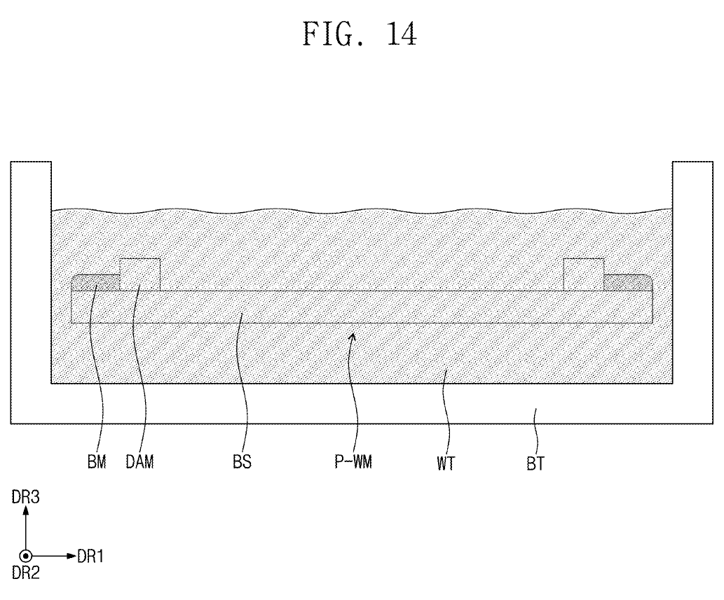

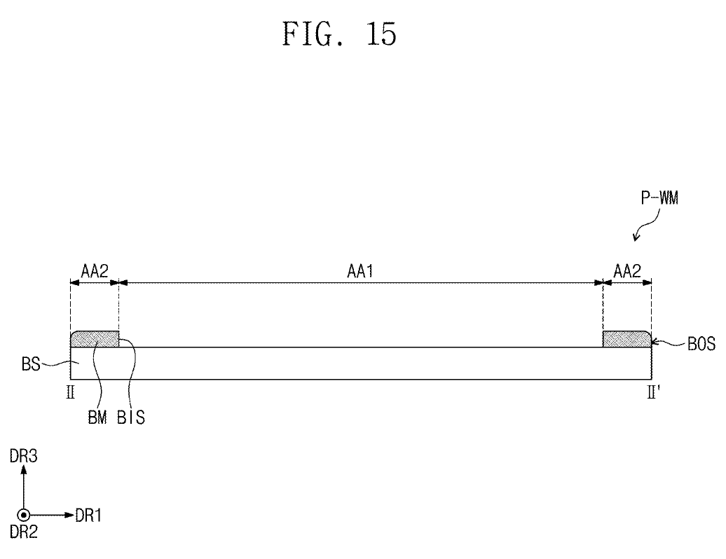

Thereafter, referring to FIGS. 14 and 15, the act of removing the applied guide dam (S400) (see FIG. 5) may be performed.

In this disclosure, a “preliminary-window P-WM” may be a member placed during the manufacturing process of the window WM (see FIG. 4B) and may be used as a general term referring to a member before the window is completed.

In one or more embodiments, the peelable ink PI may include a resin having a hydrogen bond. In one or more embodiments, the act of removing the applied peelable ink (S400) may include an act of dipping the base substrate BS in an aqueous solution WT. The act of removing the applied peelable ink (S400) may be referred to as an act of cleaning the preliminary-window P-WM. The aqueous solution WT may include water.

However, embodiments of the present disclosure are not limited thereto. For example, the peelable ink PI may include a resin including carbonyl group. In one or more embodiments, the act of removing the applied peelable ink (S400) may include an act of dipping the preliminary-window WM in the aqueous solution including sodium hydroxide.

The act of removing the guide dam (S400) (see FIG. 5) described with reference to FIG. 14 may provide an effect of cleaning the base substrate BS and the bezel pattern BM. For example, the manufacturing method for a window according to the present disclosure may make it possible to not only remove foreign substances generated during the window manufacturing process but also to remove the guide dam DAM that has played its role. Accordingly, the manufacturing process may be simplified, thereby saving time and cost.

Referring to FIG. 15, the bezel pattern BM may have an asymmetrical shape on a cross-section. Since the inner surface BIS of the bezel pattern BM is in contact with the guide dam DAM and the outer surface BOS of the bezel pattern BM is not in contact with the guide dam DAM, the inner surface BIS may have a relatively flat surface compared to the outer surface BOS.

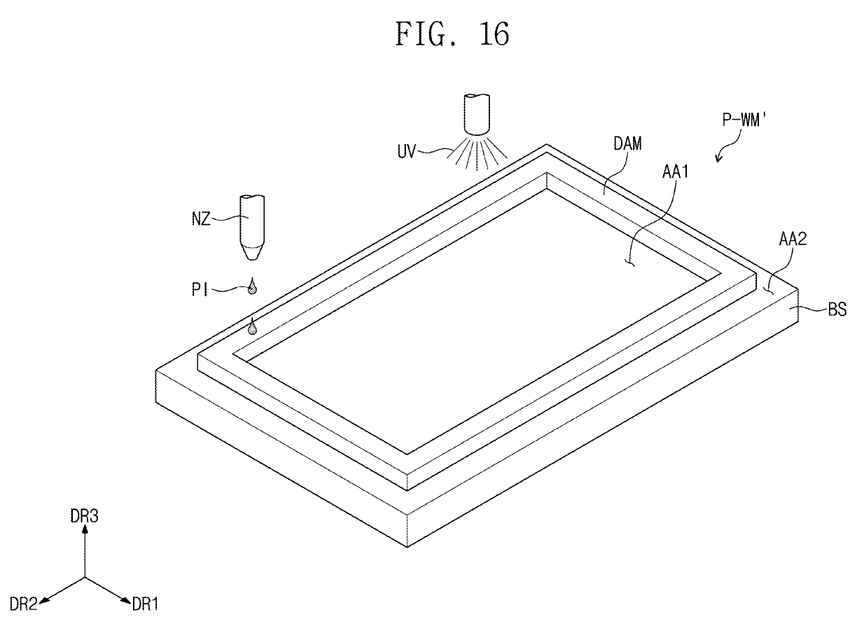

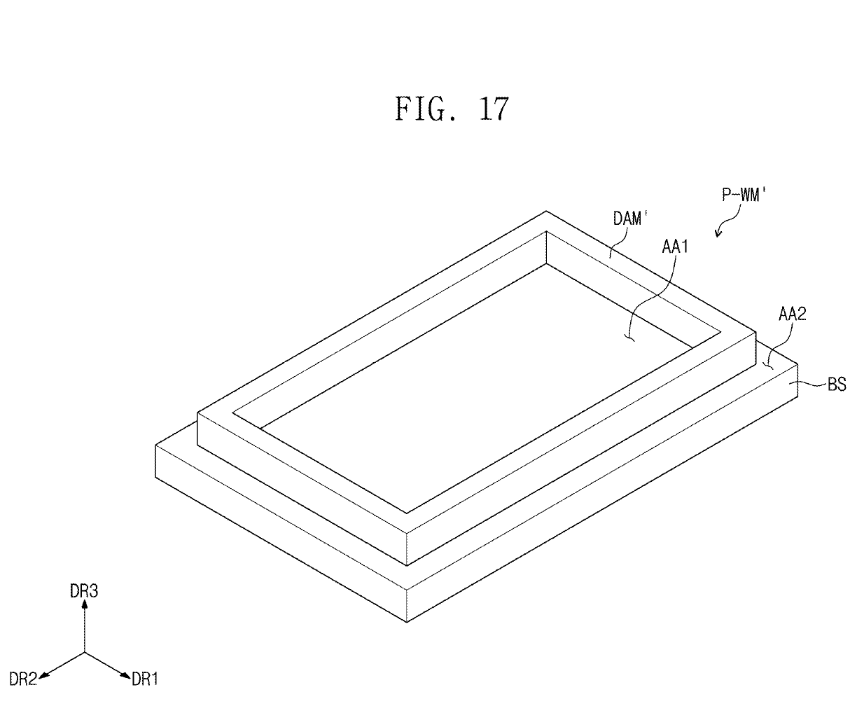

FIGS. 16 and 17 are views illustrating respective acts of a manufacturing method for a window according to one or more embodiments of the present disclosure. The same/similar components described with reference to FIGS. 1-15 are denoted as the same/similar numerals or symbols, and the duplicate descriptions are not provided, and the differences are mainly described.

Referring to FIGS. 16 and 17, after the act of forming the guide dam (S200) (see FIG. 5), an act of curing a guide dam DAM' by irradiating the guide dam DAM with ultraviolet rays may be further included.

Thereafter, the manufacturing method for a window according to the present disclosure may further include, after the act of curing the guide dam DAM', an act of re-applying the peelable ink PI onto the guide dam DAM'.

For example, if there is an embodiment where the guide dam DAM', which is formed by a single ejection of the peelable ink PI, does not have a sufficiently greater height than the bezel pattern BM (see FIG. 12), it may be possible to increase the height of the guide DAM' by curing the guide DAM' and re-applying the peelable ink PI.

According to one or more embodiments of the present disclosure, a window in which a bezel pattern for light blocking is formed on a bezel portion is provided, and thus a manufacturing method for a window having improved reliability may be provided.

The description above has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the claims. Therefore, the technical scope of the present disclosure is not to be limited to the contents stated in the detailed description of the disclosure, but should be determined by the claims and their equivalents.

What is claimed is:

1. A manufacturing method for a window, comprising:
providing a base substrate comprising a first region and a second region adjacent to the first region;
forming a guide dam by applying a peelable ink onto a portion of the first region adjacent to the second region;
forming a bezel pattern by applying a bezel ink onto the second region; and
removing the guide dam.

2. The manufacturing method of claim 1, wherein a height of the guide dam is greater than a height of the bezel pattern.

3. The manufacturing method of claim 1, wherein a height of the guide dam is 0.1 mm to 1.0 mm.

4. The manufacturing method of claim 1, wherein a height of the bezel pattern is 0.01 mm to 0.02 mm.

5. The manufacturing method of claim 1, wherein the forming of the guide dam comprises jetting the peelable ink onto the base substrate through an inkjet process.

6. The manufacturing method of claim 1, wherein the forming of the bezel pattern comprises applying the bezel ink onto the base substrate through a screen-printing process.

7. The manufacturing method of claim 1, wherein the peelable ink comprises a resin having a hydrogen bond.

8. The manufacturing method of claim 7, wherein the removing of the guide dam comprises dipping the base substrate in an aqueous solution.

9. The manufacturing method of claim 1, wherein the peelable ink comprises a resin comprising a carbonyl group.

10. The manufacturing method of claim 9, wherein the removing of the guide dam comprises dipping the base substrate in an aqueous solution comprising sodium hydroxide.

11. The manufacturing method of claim 1, further comprising, after the forming of the guide dam, re-applying the peelable ink onto the guide dam.

12. The manufacturing method of claim 1, further comprising, after the forming of the guide dam, curing the guide dam by irradiating the guide dam with ultraviolet rays.

13. The manufacturing method of claim 12, further comprising, after the curing of the guide dam, re-applying the peelable ink onto the guide dam.

14. The manufacturing method of claim 1, wherein the guide dam and the bezel pattern are in direct contact with each other.

15. The manufacturing method of claim 1, wherein, on a plane, an inner edge of the bezel pattern overlaps a boundary between the first region and the second region.

16. The manufacturing method of claim 1, wherein the bezel pattern has an asymmetrical shape on a cross-section.

17. The manufacturing method of claim 1, wherein the bezel pattern has a light blocking property.

18. The method of claim 1, wherein the bezel ink comprises either polyurethane or polyacrylate.

19. An electronic device comprising:
a window manufactured by a window manufacturing method comprising providing a base substrate comprising a first region and a second region adjacent to the first region, forming a guide dam by applying a peelable ink onto a portion of the first region adjacent to the second region, forming a bezel pattern by applying a bezel ink onto the second region, and removing the guide dam; and
a display panel under the window.

20. The electronic device of claim 19, wherein the bezel pattern is formed on a surface where the window faces the display panel.
